(19) United States
(12) Patent Application Publication
(10) Pub. No.: US 2017/0092791 A1
(43) Pub. Date: Mar. 30, 2017

(54) SOLAR CELL ELEMENT

(71) Applicant: KYOCERA CORPORATION, Kyoto (JP)

(72) Inventor: Hironori KII, Soraku-gun, Kyoto (JP)

(21) Appl. No.: 15/312,600

(22) PCT Filed: May 22, 2015
(86) PCT No.: PCT/JP2015/064790

§ 371 Date: Nov. 18, 2016

(30) Foreign Application Priority Data
May 26, 2014 (JP) 2014-107886

(51) Int. Cl. H01L 31/0224; H01L 31/0216

(52) U.S. Cl. CPC H01L 31/022466; H01L 31/02167; H01L 31/022433

(57) ABSTRACT

A solar cell element according to an embodiment of the present invention includes a p-type semiconductor layer; an n-type semiconductor layer disposed on a first main surface of the p-type semiconductor layer; an insulating layer disposed on a first main surface of the n-type semiconductor layer, and including a through hole in a thickness direction; an electrode disposed on a portion of the first main surface of the n-type semiconductor layer in the through hole of the insulating layer, and being thicker than the insulating layer; and a conductor layer disposed on a first main surface of the insulating layer, being out of contact with the electrode, and having a lower work function than the n-type semiconductor layer.

### TECHNICAL FIELD

The present invention relates to a layer structure of a solar cell element with improved power generation efficiency.

### BACKGROUND ART

A typical solar cell element includes an n-type semiconductor layer and a p-type semiconductor layer that form a pn junction, each of the n-type semiconductor layer and the p-type semiconductor layer being provided with an electrode. A current is drawn from the solar cell by collecting majority carriers from the n-type semiconductor layer and the p-type semiconductor layer through the electrodes.

Japanese Unexamined Patent Application Publication (Translation of PCT Application) No. 2013-524524 states that a surface of an n-type semiconductor layer or a p-type semiconductor layer is covered with a passivation layer (insulating layer) in order to protect the surface of the n-type semiconductor layer or the p-type semiconductor layer.

In the solar cell element, interface states are present between the passivation film and the n-type semiconductor layer or the p-type semiconductor layer. Thus, majority carriers in the n-type semiconductor layer or the p-type semiconductor layer can be recombined with minor carriers of the n-type semiconductor layer or the p-type semiconductor layer at the interface states. Hence, the collection efficiency of majority carriers in the solar cell element can be reduced to reduce the power generation efficiency of the solar cell element.

The present invention has been accomplished in light of the foregoing circumstances and aims to provide a solar cell element with improved power generation efficiency.

### SUMMARY OF INVENTION

A solar cell element according to an embodiment of the present invention includes a p-type semiconductor layer; an n-type semiconductor layer disposed on a first main surface of the p-type semiconductor layer; an insulating layer disposed on a first main surface of the n-type semiconductor layer, and including a through hole in a thickness direction; an electrode disposed on a portion of the first main surface of the n-type semiconductor layer in the through hole of the insulating layer, and being thicker than the insulating layer; and a conductor layer disposed on a first main surface of the insulating layer, being out of contact with the electrode, and having a lower work function than the n-type semiconductor layer.

A solar cell element according to an embodiment of the present invention includes an n-type semiconductor layer; a p-type semiconductor layer disposed on a first main surface of the n-type semiconductor layer; an insulating layer disposed on a first main surface of the p-type semiconductor layer, and including a through hole in a thickness direction; an electrode disposed on a portion of the first main surface of the p-type semiconductor layer in the through hole of the insulating layer, and being thicker than the insulating layer; and a conductor layer disposed on a first main surface of the insulating layer, being out of contact with the electrode, and having a higher work function than the p-type semiconductor layer.

In the solar cell element according to an embodiment of the present invention, the existence probability of minor carriers in an n-type semiconductor layer or a p-type semiconductor layer is reduced; hence, minor carriers in the n-type semiconductor layer or the p-type semiconductor layer are less likely to approach the interface between an insulating layer and the n-type semiconductor layer or the p-type semiconductor layer. Thus, a recombination of major carriers in the n-type semiconductor layer or the p-type semiconductor layer with the minor carriers in the n-type semiconductor layer or the p-type semiconductor layer is reduced at interface states at the interface between the insulating layer and the n-type semiconductor layer or the p-type semiconductor layer. Therefore, the collection efficiency of the majority carriers in the n-type semiconductor layer or the p-type semiconductor layer is improved, thereby leading to improvement in power generation efficiency.

### BRIEF DESCRIPTION OF DRAWINGS

FIG. 1 is a cross-sectional view of a solar cell element according to an embodiment of the present invention.

FIG. 2 is a plan view of a solar cell element according to an embodiment of the present invention.

FIG. 3 is part of a band diagram of a solar cell element according to an embodiment of the present invention.

FIG. 4 is part of a band diagram of a solar cell element according to an embodiment of the present invention.

FIG. 5 is a cross-sectional view of a solar cell element according to an embodiment of the present invention.

### DESCRIPTION OF EMBODIMENTS

<Solar Cell Element>

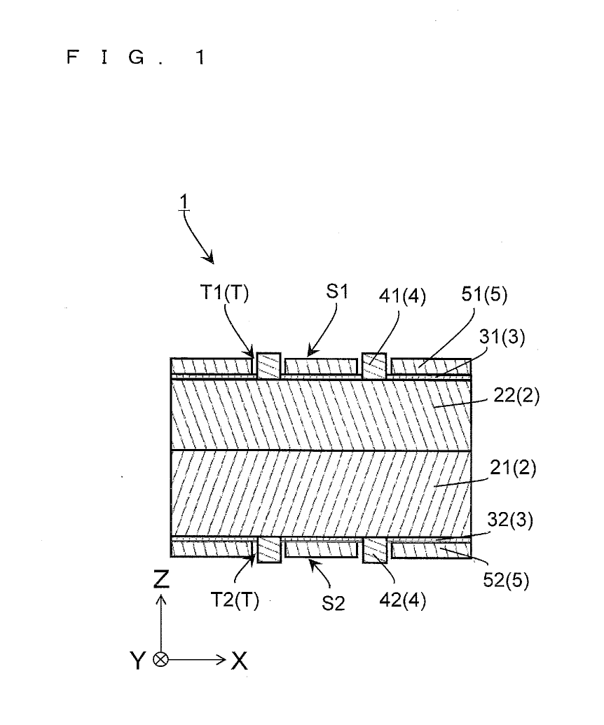

Solar cell elements according to embodiments of the present invention will be described below with reference to FIGS. 1 to 5. The present invention is not limited to these embodiments. Various changes and modifications may be made without departing from the spirit of the present invention. In each of the solar cell elements according to these embodiments, a freely selected direction may be used as an upward direction or a downward direction. In the following description, for the sake of convenience, a Cartesian coordinate system (X, Y, Z) is defined, and the positive direction of the Z-axis is defined as an upward direction. In the following description, a first main surface indicates an upper surface, and a second main surface indicates a lower surface. Needless to say, even if the upper and lower main surfaces are reversed, the present invention also includes this structure.

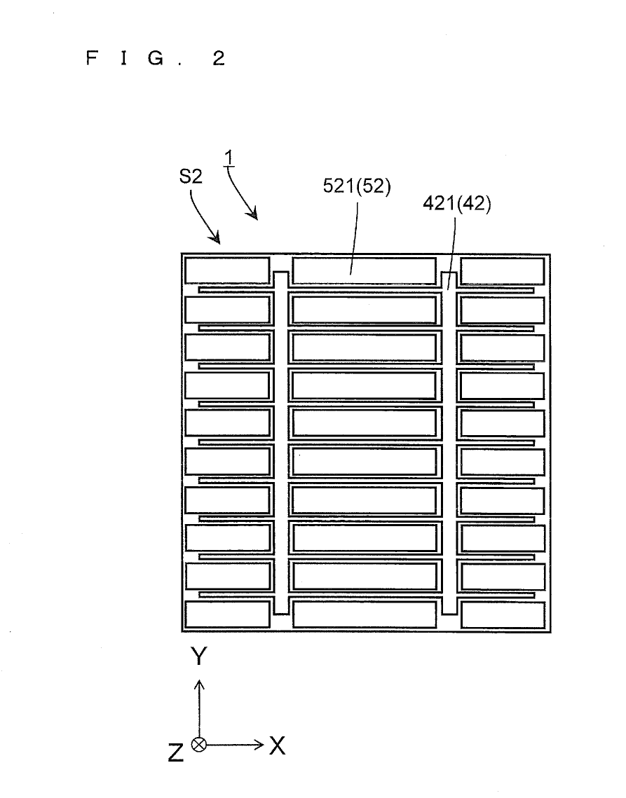

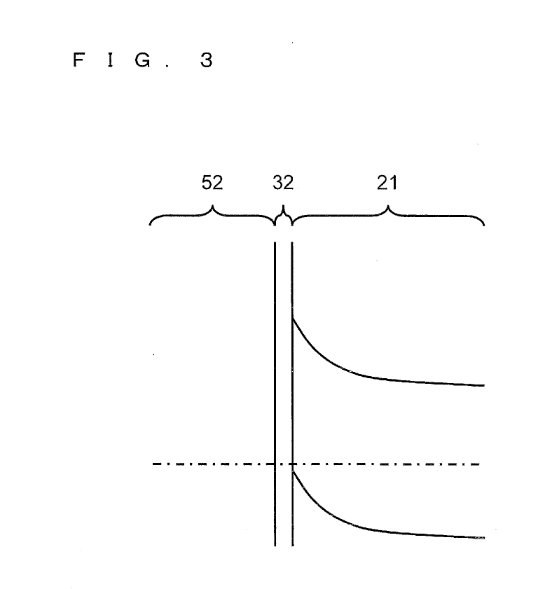

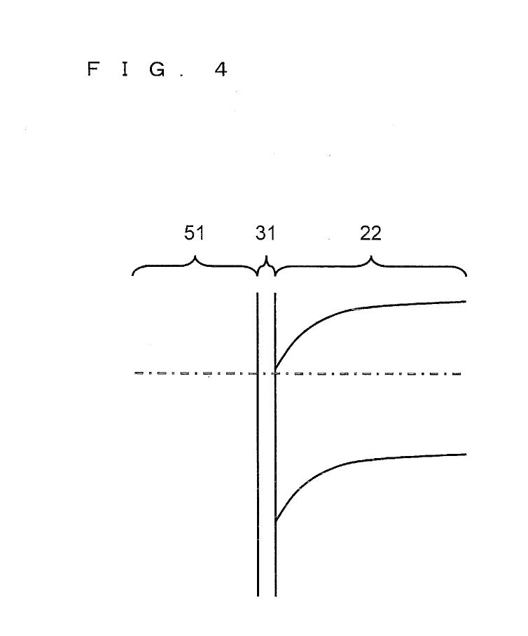

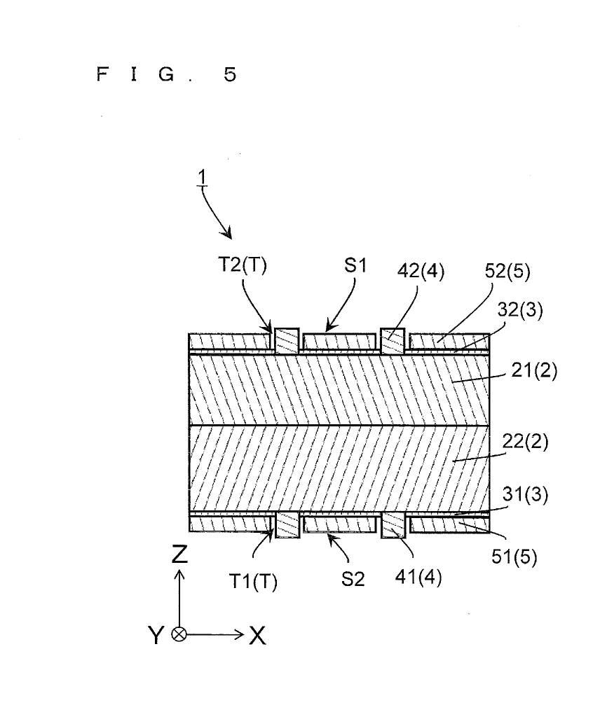

FIG. 1 is a vertical sectional view of a solar cell element according to an embodiment of the present invention. FIG. 2 is a plan view of a main surface of a solar cell element according to an embodiment of the present invention, the main surface being opposite to a light-receiving surface of the solar cell element. FIGS. 3 and 4 are each part of a band diagram of a solar cell element according to an embodiment of the present invention. An alternate long and short dashed line in each of FIGS. 3 and 4 indicates the Fermi level. FIG. 5 is a vertical sectional view of a solar cell element according to an embodiment of the present invention, the solar cell element being different from the example illustrated in FIG. 1 of the present invention.

A solar cell element 1 converts optical energy into electrical energy. As illustrated in FIG. 1, the solar cell element 1 mainly includes a semiconductor substrate 2, insulating layers 3 on the semiconductor substrate 2, electrodes 4 configured to draw current from the semiconductor substrate 2, and conductor layers 5 on the insulating layers 3. Specifically, each of the insulating layers 3 is disposed over a surface of the semiconductor substrate 2 and includes through holes T in the thickness direction. Each of the electrodes 4 is disposed in a corresponding one of the through holes T and on a portion of a main surface of the semiconductor substrate 2. The conductor layers 5 are disposed on first main surfaces of the insulating layers 3 and are out of direct contact with the electrodes 4.

The semiconductor substrate 2 has an internal electric field. When carriers generated by exposure to sunlight transfer, a current flows. As illustrated in FIG. 1, the semiconductor substrate 2 includes a p-type semiconductor layer 21 and an n-type semiconductor layer 22 on a first main surface of the p-type semiconductor layer 21. The n-type semiconductor layer 22 is disposed on the first main surface of the p-type semiconductor layer 21 and forms a pn junction with the p-type semiconductor layer 21. Thus, majority charge carriers therein are neutralized together to form a depletion layer at the interface between the p-type semiconductor layer 21 and the n-type semiconductor layer 22, thereby generating the internal electric field in the semiconductor substrate 2.

The majority carriers indicate holes in the p-type semiconductor layer 21 and electrons in the n-type semiconductor layer 22. Minor carriers indicate electrons in the p-type semiconductor layer 21 and holes in the n-type semiconductor layer 22.

The p-type semiconductor layer 21 is a film-like member composed of a semiconductor, contains an acceptor as an impurity, and exhibits p-type conductivity. An example of the shape of the p-type semiconductor layer 21 in plan is, but not particularly limited to, a quadrangular shape. The p-type semiconductor layer 21 is composed of, for example, single-crystal or polycrystalline silicon (Si) and contains, for example, boron (B) or gallium (Ga) serving as an acceptor. In this embodiment, the p-type semiconductor layer 21 is a main portion of the semiconductor substrate 2. The p-type semiconductor layer 21 according to this embodiment has a thickness of, for example, 100 μm or more and 300 μm or less. The p-type semiconductor layer 21 has a work function of, for example, 4.7 eV or more and 5.1 eV or less. Although the p-type semiconductor layer 21 is a main portion of the semiconductor substrate 2 in this embodiment, the n-type semiconductor layer 22 may be a main portion of the semiconductor substrate 2. In the following description, the work function refers to a difference between the vacuum level and the Fermi level.

The work function of the p-type semiconductor layer 21 may be measured by, for example, the Kelvin method (vibrating capacitor method). In the following description, the measurement of the work function is performed in the same way as for the p-type semiconductor layer 21, unless otherwise stated.

The n-type semiconductor layer 22 is a film-like member composed of a semiconductor, contains a donor as an impurity, and exhibits n-type conductivity. An example of the shape of the n-type semiconductor layer 22 in plan is, but not particularly limited to, a quadrangular shape. The shape of the n-type semiconductor layer 22 in plan is the same as that of, for example, the p-type semiconductor layer 21. The n-type semiconductor layer 22 is composed of, for example, single-crystal or polycrystalline silicon (Si) and contains, for example, phosphorus (P) or antimony (Sb) serving as a donor. The n-type semiconductor layer 22 has a thickness of, for example, 0.1 μm or more and 5 μm or less. The n-type semiconductor layer 22 has a work function of, for example, 4 eV or more and 4.4 eV or less.

The solar cell element 1 includes a first surface S1 serving as a light-receiving surface and a second surface S2 serving as a back surface opposite the light-receiving surface.

Each of the insulating layers 3 is what is called a passivation film and disposed on a corresponding one of the main surfaces of the semiconductor substrate 2 to protect the semiconductor substrate 2. As illustrated in FIG. 1, the insulating layers 3 include a first insulating layer 31 on a first main surface of the n-type semiconductor layer 22; and a second insulating layer 32 on a second main surface of the p-type semiconductor layer 21. The insulating layers 3 include the through holes T (first through holes T1 and second through holes T2) in the first insulating layer 31 and the second insulating layer 32 in the thickness direction in order to connect the electrodes 4 to the semiconductor substrate 2.

The first insulating layer 31 is a film-like member composed of an insulating material. The shape of the first insulating layer 31 in plan is the same as that of the n-type semiconductor layer 22. The first insulating layer 31 covers the first main surface of the n-type semiconductor layer 22. The first insulating layer 31 is composed of an insulating material, for example, silica (SiO₂) or silicon nitride (SiNₓ). The first insulating layer 31 has a thickness of, for example, 5 nm or more and 30 nm or less.

The second insulating layer 32 is a film-like member composed of an insulating material. The shape of the second insulating layer 32 in plan is the same as that of the p-type semiconductor layer 21. The second insulating layer 32 covers the second main surface of the p-type semiconductor layer 21. The second insulating layer 32 is composed of an insulating material, for example, silica (SiO₂) or silicon nitride (SiNₓ). The second insulating layer 32 has a thickness of, for example, 5 nm or more and 30 nm or less.

The electrodes 4 are configured to draw current from the semiconductor substrate 2. As illustrated in FIG. 1, the electrodes 4 include first electrodes 41 connected to the n-type semiconductor layer 22; and second electrodes 42 connected to the p-type semiconductor layer 21. Each of the electrodes 4 has a greater thickness than a corresponding one of the insulating layers 3.

The first electrodes 41 and the second electrodes 42 are members composed of a conductor. The first electrodes 41 include strip-shaped first strip electrodes 411. The second electrodes 42 include strip-shaped second strip electrodes 421. As illustrated in FIG. 2, the second strip electrodes 421 of the second electrodes 42 are disposed in the form of a grid. As with the second electrodes 42, the first strip electrodes 411 of the first electrodes 41 are disposed in the form of a grid. The first electrodes 41 are composed of a metal material such as silver (Ag). The second electrodes 42 are composed of a metal material such as aluminum (Al).

The conductor layers 5 are disposed over main surfaces of the insulating layers 3 and are configured to reduce the recombination of carriers in the semiconductor substrate 2 at the interfaces between the semiconductor substrate 2 and the insulating layers 3. As illustrated in FIG. 1, the conductor layers 5 include first conductor layers 51 on a main surface of the first insulating layer 31; and second conductor layers 52 on a main surface of the second insulating layer 32. The first conductor layers 51 include film-like first conductor strips 511. The second conductor layers 52 include film-like second conductor strips 521. As illustrated in FIG. 2, for example, the second conductor strips 521 of the second conductor layers 52 are disposed between the second strip electrodes 421. The first conductor strips 511 of the first conductor layers 51 are disposed between the first strip electrodes 411 in the same way as the second conductor layers 52.

The second conductor layers 52 are film-like members composed of a conductor. The second conductor layers 52 are composed of a metal material, for example, nickel (Ni) or gold (Au), or a material, for example, ITO. Each of the second conductor layers 52 has a thickness of, for example, 0.01 μm or more and 1 μm or less. Each of the second conductor layers 52 has a work function of, for example, 4.8 eV or more.

The term “conductor” used here indicates a material in which resistance to electric current increases when the material is heated. The term “semiconductor” indicates a material in which resistance to electric current decreases when the material is heated.

The second conductor layers 52 have a higher work function than the p-type semiconductor layer 21. Thus, the power generation efficiency is improved, compared with conventional solar cell elements without a conductor layer. Specifically, when the second conductor layers 52 are disposed on the p-type semiconductor layer 21 and have a higher work function than the p-type semiconductor layer 21, the energy of electrons in the p-type semiconductor layer 21 is higher than the energy of electrons in the second conductor layers 52. Thus, the energy of electrons in the p-type semiconductor layer 21 and the energy of electrons in the second conductor layers 52 will be brought into a state of equilibrium. In this case, the work function of the p-type semiconductor layer 21 increases in response to the second conductor layers 52, as illustrated in FIG. 3. The existence probability of holes in the p-type semiconductor layer 21 increases with decreasing distance from the second conductor layers 52. In other words, the existence probability of electrons in the p-type semiconductor layer 21 decreases with decreasing distance from the second conductor layers 52. Thus, the number of electrons serving as minor carriers in the p-type semiconductor layer 21 is reduced at the interface between the second insulating layer 32 and the p-type semiconductor layer 21, thereby inhibiting recombination with holes serving as majority carriers at the interface and improving the power generation efficiency of the solar cell element 1.

The work function of the second conductor layers 52 is, for example, 1.01 or more times and 1.15 or less times the work function of the p-type semiconductor layer 21.

The first conductor layers 51 are film-like members composed of a conductor. The first conductor layers 51 are composed of a metal material, for example, aluminum (Al) or magnesium (Mg), or a material, for example, a conductive mayenite-type compound. Each of the first conductor layers 51 has a thickness of, for example, 0.01 μm or more and 1 μm or less. Each of the first conductor layers 51 has a work function of, for example, 4.3 eV or less.

The first conductor layers 51 have a lower work function than the n-type semiconductor layer 22. Thus, the energy of electrons in the first conductor layers 51 is higher than the energy of electrons in the n-type semiconductor layer 22. As illustrated in FIG. 4, therefore, the work function of the n-type semiconductor layer 22 decreases in response to the first conductor layers 51. The existence probability of electrons in the n-type semiconductor layer 22 increases with decreasing distance from the first conductor layers 51. Furthermore, the existence probability of holes in the n-type semiconductor layer 22 decreases with decreasing distance from the first conductor layers 51. Accordingly, the recombination of minor carriers and majority carriers in the n-type semiconductor layer 22 is reduced at the interface between the n-type semiconductor layer 22 and the first insulating layer 31.

The work function of the first conductor layers 51 is 0.6 or more times and 0.97 or less times the work function of the n-type semiconductor layer 22.

The conductor layers 5 are out of direct contact with the electrodes 4, as described above. In other words, the conductor layers 5 are remote from the electrodes 4 and insulated from the electrodes 4.

The conductor layers 5 on the side of the first surface S1 are preferably composed of a translucent conductor. First main surfaces of the conductor layers 5 may serve as light-receiving surfaces. In this case, the conductor layers 5 are formed on the light-receiving surface of the solar cell element 1 and disposed on the side of the light-receiving surface, thereby effectively generating photocurrent.

The work function of the second conductor layers 52 may be lower than that of the second electrodes 42. In this case, the existence probability of holes at interfaces between the p-type semiconductor layer 21 and the second electrodes 42 is higher than the existence probability of holes at the interface between the p-type semiconductor layer 21 and the second insulating layer 32. Thus, the accumulation of holes at the interface between the p-type semiconductor layer 21 and the second insulating layer 32 is reduced to improve the power generation efficiency of the solar cell element 1.

The work function of the first conductor layers 51 may be higher than that of the first electrodes 41. In this case, the existence probability of electrons at interfaces between the n-type semiconductor layer 22 and the first electrodes 41 is higher than the existence probability of electrons at the interface between the n-type semiconductor layer 22 and the first insulating layer 31. Thus, the accumulation of electrons at the interface between the n-type semiconductor layer 22 and the first insulating layer 31 is reduced to improve the power generation efficiency of the solar cell element 1.

The present invention is not limited to this embodiment. Various changes and modifications may be made without departing from the spirit of the present invention.

In the foregoing description, a structure in which the n-type semiconductor layer 22 is stacked on the first main surface of the p-type semiconductor layer 21 is used as an example. As illustrated in FIG. 5, however, a structure in which the p-type semiconductor layer 21 is stacked on the first main surface of the n-type semiconductor layer 22 may be used. In this case, the first insulating layer 31, the first electrodes 41, and the first conductor layers 51 are located on the side of a second main surface of the n-type semiconductor layer 22. The second insulating layer 32, the second electrodes 42, and the second conductor layers 52 are located on the side of the first main surface of the p-type semiconductor layer 21.

<Method For Producing Solar Cell Element>

A method for producing a solar cell element according to an embodiment of the present invention will be described. The solar cell element according to the embodiment is produced primarily through the formation of the semiconductor substrate 2, the formation of the insulating layers 3, the formation of the conductor layers 5, and the formation of the electrodes 4.

(Formation of Semiconductor Substrate)

The semiconductor substrate 2 is formed. To form the semiconductor substrate 2, a substrate formed of the p-type semiconductor layer 21 or the n-type semiconductor layer 22 is first prepared. Subsequently, a semiconductor layer of a conductivity type opposite to that of the substrate is formed to form the semiconductor substrate 2. In the following description of the embodiment, the p-type semiconductor layer 21 serving as a substrate is used as an example.

To prepare the substrate, a crystal ingot is first formed. When the substrate (p-type semiconductor layer 21) is a single-crystal silicon substrate, the crystal ingot is formed by, for example, a pulling method. When the substrate (p-type semiconductor layer 21) is a polycrystalline silicon substrate, the crystal ingot is formed by, for example, a casting method.

The resulting ingot is sliced into, for example, 250 μm or less in thickness, thereby preparing the substrate. Preferably, surfaces of the substrate are lightly etched with, for example, NaOH, KOH, hydrofluoric acid, or a mixture of hydrofluoric acid and nitric acid in order to remove mechanical damage and contamination of the surfaces of the substrate due to the cutting of the ingot. After this etching step, a fine irregular structure is more preferably formed on the surfaces of the substrate by a wet etching method. If wet-etching conditions are changed, it is possible to clean the surfaces of the substrate and form the fine irregular structure.

The n-type semiconductor layer 22 is formed on the first main surface of the substrate (p-type semiconductor layer 21). The n-type semiconductor layer 22 may be formed by, for example, an application and thermal diffusion process in which P₂O₅ in the form of a paste is applied to a surface of the substrate and thermally diffused, a vapor-phase thermal diffusion process in which gaseous POCl₃ (phosphorus oxychloride) is used as a diffusion source, or an ion implantation process in which phosphorus ions are directly diffused. The n-type semiconductor layer 22 is formed so as to have a depth of about 0.2 to about 2 μm and a sheet resistance of about 40 to about 150Ω/sq. A method for forming the n-type semiconductor layer 22 is not limited to the foregoing methods. A hydrogenated amorphous silicon film or a crystalline silicone film including a microcrystalline silicon film may be formed by, for example, thin-film technology.

When the n-type semiconductor layer 22 is formed also on the second main surface of the substrate (p-type semiconductor layer 21), only the n-type semiconductor layer 22 on the second main surface is removed to expose the main surface of the substrate (p-type semiconductor layer 21). The removal of the n-type semiconductor layer 22 is performed by, for example, dipping only the second main surface side of the substrate in a solution of hydrofluoric acid and nitric acid. Subsequently, phosphosilicate glass adhering to a surface of the n-type semiconductor layer 22 in the formation of the n-type semiconductor layer 22 is removed by etching. In this way, the n-type semiconductor layer 22 on the side of the second main surface of the substrate is removed with the phosphosilicate glass left. The phosphosilicate glass serves as an etch mask and thus inhibits the removal of and damage to the n-type semiconductor layer 22 on the side of the first main surface of the substrate. The same structure may be formed by a process in which a diffusion mask is formed on the second main surface of the substrate in advance, the n-type semiconductor layer 22 is formed by, for example, a vapor-phase thermal diffusion process, and then the diffusion mask is removed.

As described above, the semiconductor substrate 2 including the p-type semiconductor layer 21 (substrate) and the n-type semiconductor layer 22 is formed.

(Formation of Insulating Layer)

The insulating layers 3 (the first insulating layer 31 and the second insulating layer 32) are formed. The insulating layers 3 are formed by, for example, a thermal oxidation method, a PECVD method, or a sputtering method. For example, when the insulating layers 3 are formed by the PECVD method, a gas mixture of silane (SiH₄) gas (10 to 200 sccm) and ammonia (NH₃) gas (10 to 500 sccm) is used. The gas mixture is converted into plasma states by glow discharge decomposition at a substrate temperature of 200° C. to 500° C., a gas pressure of 5 to 300 Pa, a plasma excitation frequency of 13.56 to 40.68 MHz, and a plasma power density of 0.002 to 1 W/cm², and then deposition is performed on the semiconductor substrate 2 to form the insulating layers 3. The insulating layers 3 include the through holes T. The through holes T may be formed by, for example, removing portions of the insulating layers 3 at a spacing of 200 μm to 1 mm using a sandblasting method, a mechanical scribing method, a chemical etching method, a laser method, or the like. The through holes T may also be formed by forming the insulating layers 3 with a predetermined form using, for example, masks.

(Formation of Conductor Layer)

The conductor layers 5 (the first conductor layers 51 and the second conductor layers 52) are formed. The formation of the conductor layers 5 may be performed by, for example, a vapor deposition method or a sputtering method with, for example, metal masks.

(Formation of Electrode)

The electrodes 4 (the first electrodes 41 and the second electrodes 42) are formed.

The second electrodes 42 are formed with, for example, an aluminum paste containing an aluminum (Al) powder and an organic vehicle. The paste is applied to portions of the second insulating layer 32 in the through holes T. As an application method, a screen printing method or the like may be employed. A method is preferred in which after the application of the paste as described above, a solvent is evaporated at a predetermined temperature to dry the paste because the paste is less likely to adhere to other portions during an operation. Then the p-type semiconductor layer 21 is baked in a baking oven at a maximum temperature of 600° C. to 850° C. for about several tens of seconds to about several tens of minutes to form the second electrodes 42.

The first electrodes 41 are formed with, for example, a silver paste containing a metal powder composed of silver (Ag), an organic vehicle, and a glass frit. The silver paste is applied to the main surface of the n-type semiconductor layer 22 and then baked at a maximum temperature of 600° C. to 850° C. for about several tens of seconds to about several tens of minutes to penetrate the insulating layer 3 (first insulating layer 31) by a fire-through process, thereby electrically connecting the first electrodes 41 to the n-type semiconductor layer 22. As a method of applying the silver paste, a screen printing method or the like may be employed. Preferably, after the application, a solvent is evaporated at a predetermined temperature to dry the paste.

As described above, the solar cell element 1 is produced.

### REFERENCE SIGNS LIST

1 solar cell element
2 semiconductor substrate
21 p-type semiconductor layer
22 n-type semiconductor layer
3 insulating layer
31 first insulating layer
32 second insulating layer
4 electrode
41 first electrode
411 first strip electrode
42 second electrode
421 second strip electrode
5 conductor layer
51 first conductor layer
511 first conductor strip
52 second conductor layer
521 second conductor strip
S1 first surface (light-receiving surface)
S2 second surface
T through hole
T1 first through hole
T2 second through hole

1. A solar cell element, comprising:
a p-type semiconductor layer;
an n-type semiconductor layer disposed on a first main surface of the p-type semiconductor layer;
an insulating layer disposed on a first main surface of the n-type semiconductor layer, and comprising a through hole in a thickness direction;
an electrode disposed on a portion of the first main surface of the n-type semiconductor layer in the through hole of the insulating layer, and being thicker than the insulating layer; and
a conductor layer:
disposed on a first main surface of the insulating layer;
being out of contact with the electrode; and
having a lower work function than the n-type semiconductor layer.

2. The solar cell element according to claim 1, further comprising:
a second insulating layer:
disposed on a second main surface, one of main surfaces of the p-type semiconductor layer, opposite to the first main surface on which the n-type semiconductor layer is disposed; and
comprising a second through hole in a thickness direction;
a second electrode disposed on a portion of the second main surface of the p-type semiconductor layer in the second through hole of the second insulating layer, and being thicker than the second insulating layer; and
a second conductor layer:
disposed on the second insulating layer;
being out of contact with the second electrode; and
having a higher work function than the p-type semiconductor layer.

3. A solar cell element, comprising:
an n-type semiconductor layer;
a p-type semiconductor layer disposed on a first main surface of the n-type semiconductor layer;
an insulating layer disposed on a first main surface of the p-type semiconductor layer, and comprising a through hole in a thickness direction;
an electrode disposed on a portion of the first main surface of the p-type semiconductor layer in the through hole of the insulating layer, and being thicker than the insulating layer; and
a conductor layer:
disposed on a first main surface of the insulating layer;
being out of contact with the electrode; and
having a higher work function than the p-type semiconductor layer.

4. The solar cell element according to claim 1, wherein
the conductor layer comprises a translucent material, and the first main surface serves as a light-receiving surface.

5. The solar cell element according to claim 2, wherein the conductor layer comprises a translucent material, and the first main surface serves as a light-receiving surface.

6. The solar cell element according to claim 3, wherein the conductor layer comprises a translucent material, and the first main surface serves as a light-receiving surface.
